(19) United States
(12) Patent Application Publication
(10) Pub. No.: US 2015/0214224 A1
(43) Pub. Date: Jul. 30, 2015

(54) MOS TRANSISTOR, SEMICONDUCTOR DEVICE, AND METHOD OF MANUFACTURING THE SAME

(71) Applicant: PS4 LUXCO S.A.R.L., Luxembourg (LU)

(72) Inventor: Keizo KAWAKITA, Tokyo (JP)

(73) Assignee: PS4 LUXCO S.A.R.L., Luxembourg (LU)

(21) Appl. No.: 14/679,188

(22) Filed: Apr. 6, 2015

Related U.S. Application Data
(63) Continuation of application No. 11/842,643, filed on Aug. 21, 2007, now abandoned.

(30) Foreign Application Priority Data
Aug. 23, 2006 (JP) 2006-226494

(51) Int. Cl. H01L 27/088

(52) U.S. Cl. CPC H01L 27/088

(57) ABSTRACT

In a MOS transistor having a structure in which a source and a drain are raised on a substrate by using a selective epitaxial growth technique, a bulk resistance can be reduced while an impurity concentration of a silicon layer is reduced in the selective epitaxial growth. A metal oxide semiconductor transistor includes a gate having a sidewall formed on a silicon substrate, a silicon layer formed on the silicon substrate by selective epitaxial growth, and an inclination portion inclined downward in a direction opposite to the gate on at least a portion of a cross-section including the silicon layer and the gate.

This application is a Continuation application of U.S. application Ser. No. 11/842,643 filed Aug. 21, 2007, which claims priority from Japanese Patent Application No. 2006-226494, filed on Aug. 23, 2006, the disclosure of which is incorporated herein in its entirety by reference.

### BACKGROUND OF THE INVENTION

1. Field of the Invention

The present invention relates to a metal oxide semiconductor (MOS) transistor, and more particularly to a structure and manufacturing method of a MOS transistor having a structure in which a source and a drain are raised on a substrate by using a selective epitaxial growth technique.

2. Description of the Related Art

Some MOS transistors have a structure in which a source and a drain are raised on a substrate by using a selective epitaxial growth technique. Because epitaxially grown silicon contains no impurities, this type of MOS transistors has a high resistance due to a bulk resistance. Accordingly, it is difficult to maintain an on-state current Iₒₙ of a MOS transistor.

One of methods for maintaining an on-state current Iₒₙ includes introducing impurities into a source and a drain at a high concentration after selective epitaxial growth. An ion implantation method may be used for this purpose. Alternatively, polysilicon doped at a high concentration may be brought into contact with an upper surface of a silicon layer formed by selective epitaxial growth to thereby introduce impurities. In these methods, if a silicon layer is formed with a small thickness by selective epitaxial growth, then impurities having a high concentration may be diffused to the vicinity of a gate on a substrate side. Accordingly, characteristics of the MOS transistor may be changed.

Here, current paths of an on-state current Iₒₙ in a conventional MOS transistor will be described. An on-state current Iₒₙ flows from a lower end of a sidewall of a gate to an impurity layer. In FIG. 1, each of two arrows 50 represents a current path. The current path 50 extending to a location on an impurity layer away from a gate is longer than the current path 51 extending to a location on the impurity layer near the gate. In other words, as a current path extends to a location on an impurity layer farther away from a gate, the length of the current path becomes longer.

For example, Japanese laid-open patent publication No. 11-145453 (Patent Document 1) discloses a conventional technology of the related art.

In the conventional technology, silicon is formed with a large thickness by epitaxial growth in order to reduce variations in characteristics of a MOS transistor. Alternatively, the amount of impurities to be introduced into a MOS transistor is reduced. However, in either case, a bulk resistance component is increased at those processed portions. Accordingly, an on-state current Iₒₙ of the MOS transistor cannot be maintained.

### SUMMARY OF THE INVENTION

The present invention has been made in view of the above drawbacks. It is, therefore, an exemplary object of the present invention to provide technology to reduce a bulk resistance in a MOS transistor having a structure in which a source and a drain are raised on a substrate by using a selective epitaxial growth technique and to reduce an impurity concentration of a silicon layer in the selective epitaxial growth.

It is considered that the above problems can be solved by removing a high-resistance portion before formation of a contact. Thus, the present invention proposes the following technology to achieve the above object as exemplary aspects of it.

Specifically, an exemplary aspect of the present invention proposes a metal oxide semiconductor (MOS) transistor including a gate having a sidewall formed on a silicon substrate, a silicon layer formed on the silicon substrate by selective epitaxial growth, and an inclination portion inclined downward in a direction opposite to the gate on at least a portion of a cross-section including the silicon layer and the gate.

Thus, the MOS transistor according to the exemplary aspect has the silicon layer inclined downward. With regard to current paths extending radially from a lower end of the sidewall to the silicon layer, a current path can be shortened in the inclination portion as it is located farther away from the sidewall, as compared to a conventional MOS transistor having a flat silicon layer. As a result, a bulk resistance of the silicon layer can be reduced.

### BRIEF DESCRIPTION OF THE DRAWINGS

FIG. 1 is a cross-sectional view explanatory of the length of current paths between a sidewall and an impurity layer in a conventional MOS transistor 500;

FIG. 2 is a cross-sectional view showing one of steps of manufacturing a MOS transistor 100 according to a first embodiment of the present invention;

FIG. 3 is a cross-sectional view showing one of the steps of manufacturing the MOS transistor 100 according to the first embodiment of the present invention;

FIG. 4 is a cross-sectional view showing one of the steps of manufacturing the MOS transistor 100 according to the first embodiment of the present invention;

FIG. 5 is a cross-sectional view showing one of the steps of manufacturing the MOS transistor 100 according to the first embodiment of the present invention;

FIG. 6 is a cross-sectional view showing one of the steps of manufacturing the MOS transistor 100 according to the first embodiment of the present invention;

FIG. 7 is a cross-sectional view showing one of the steps of manufacturing the MOS transistor 100 according to the first embodiment of the present invention;

FIG. 8 is a cross-sectional view showing one of the steps of manufacturing the MOS transistor 100 according to the first embodiment of the present invention;

FIG. 9 is a cross-sectional view showing one of the steps of manufacturing the MOS transistor 100 according to the first embodiment of the present invention;

FIG. 10 is a cross-sectional view showing one of the steps of manufacturing the MOS transistor 100 according to the first embodiment of the present invention;

FIG. 11 is a cross-sectional view explanatory of the length of current paths between a sidewall 7 and an impurity layer 24 in the MOS transistor 100;

FIG. 12 is a cross-sectional view showing one of steps of manufacturing a MOS transistor 200 according to a second embodiment of the present invention;

FIG. 13 is a view explanatory of a lithography mask pattern of a semiconductor device suitable for application of the MOS transistor 100 or 200;

FIG. 14 is a view explanatory of a lithography mask pattern of a semiconductor device suitable for application of the MOS transistor 100 or 200;

FIG. 15 is a cross-sectional view explanatory of a structure of a MOS transistor 300 according to a third embodiment of the present invention; and

FIG. 16 is a view explanatory of a lithography mask pattern of a semiconductor device suitable for application of the MOS transistor 300.

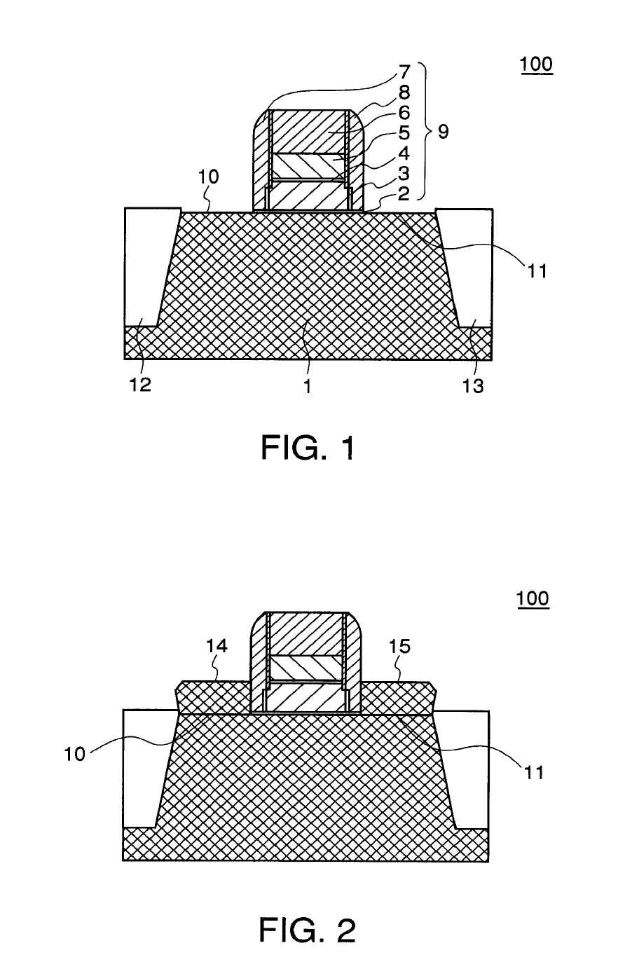

### DETAILED DESCRIPTION OF THE PREFERRED EMBODIMENTS

In a MOS transistor having a structure in which silicon of a source and a drain is raised on a substrate by using selective epitaxial growth technique, an exemplary aspect of the present invention is focused on the fact that the high resistance of the raised silicon inhibits an on-state current Iₒₙ of the transistor. Accordingly, a portion of the raised silicon is removed. As a result, the parasitic resistance of the source and the drain can be reduced, and an on-state current Iₒₙ can be improved.

A manufacturing method of a MOS transistor 100 according to a first exemplary embodiment of the present invention will be described below with reference to FIGS. 2 to 11. FIGS. 2 to 10 are cross-sectional views showing a series of steps of manufacturing a MOS transistor 100. Each of FIGS. 2 to 10 includes reference numerals necessary for explanation of each step.

As shown in FIG. 2, a gate 9 is formed on a silicon substrate 1 by a general process. The gate 9 includes a gate insulation film 2, a gate polysilicon 3, a tungsten nitride 4, a tungsten gate electrode 5, an offset insulation film 6, and sidewalls 7 and 8. A source 10 and a drain 11 are formed on the silicon substrate 1 at the left and right sides of the gate 9, respectively. Silicon oxide films 12 and 13 are formed on the left and right sides of the silicon substrate 1, respectively.

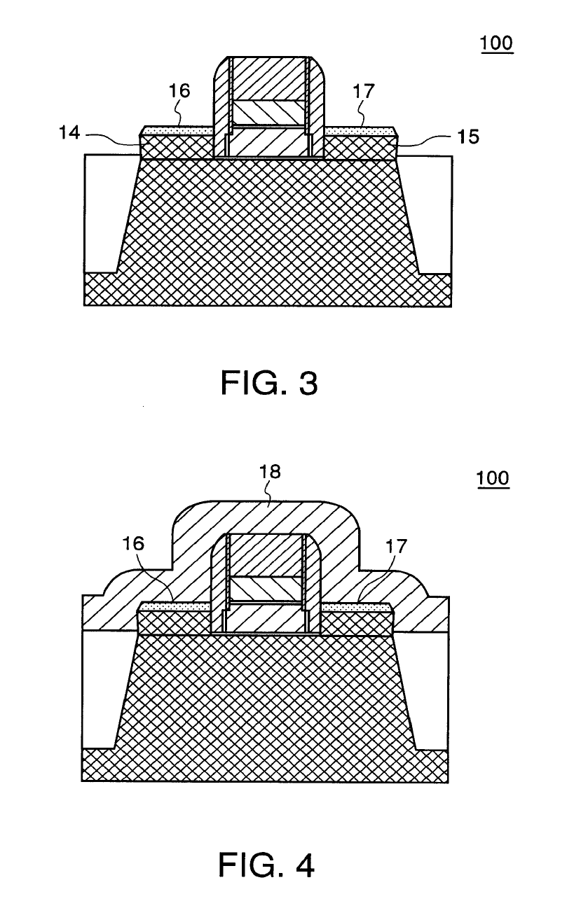

Then, as shown in FIG. 3, the source 10 and the drain 11 of the silicon substrate 1 are raised by a selective epitaxial growth technique to thereby form a structure of a MOS transistor. A silicon layer 14 is formed on the source 10, and a silicon layer 15 is formed on the drain 11.

Next, as shown in FIG. 4, an impurity having a high concentration is introduced into upper surfaces of the silicon layers 14 and 15 by an ion implantation method so as to form impurity layers 16 and 17.

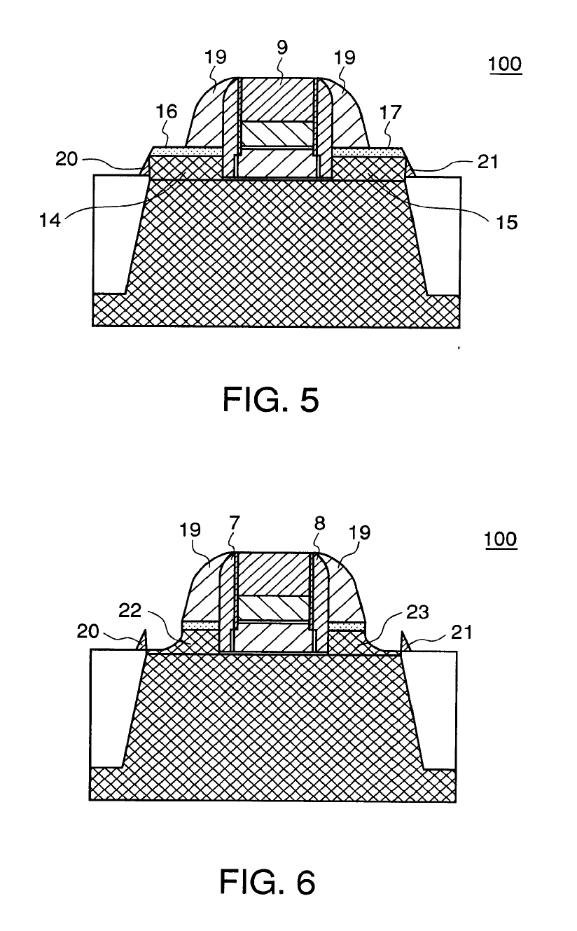

Subsequently, as shown in FIG. 5, a silicon nitride film 18 is grown on the overall surface of the substrate.

Then, as shown in FIG. 6, the silicon nitride film 18 is etched back so that silicon nitride films 19, 20, and 21 are left on the substrate after the etch-back. The silicon nitride film 19 is formed so as to surround the gate 9. The silicon nitride film 20 is formed on leftward ends of the silicon layer 14 and the impurity layer 16. The silicon nitride film 21 is formed on rightward ends of the silicon layer 15 and the impurity layer 17.

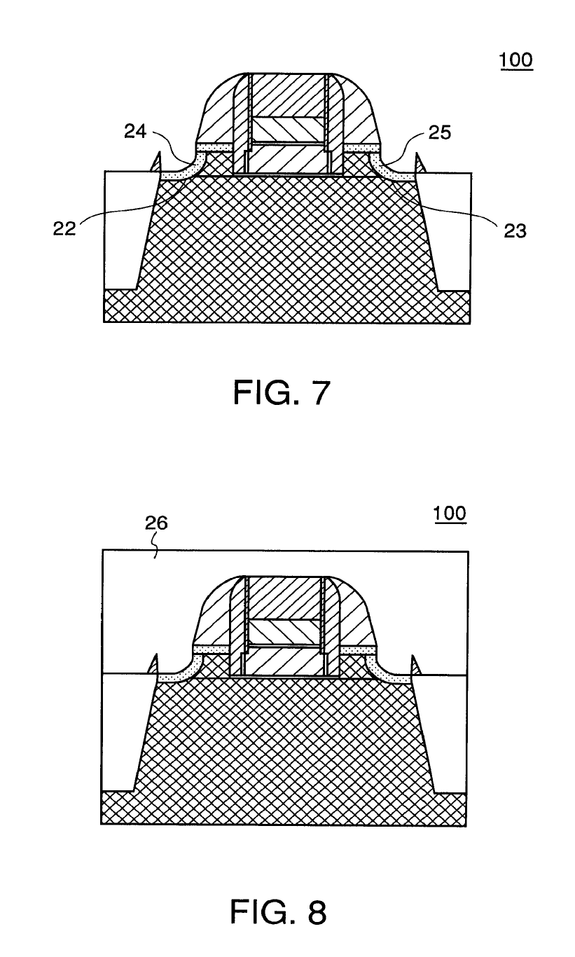

Next, while the silicon nitride films 19 and 20 are used as a mask, the silicon layer 14 and the impurity layer 16 are etched so as to form a recessed portion 22 as shown in FIG. 7. Similarly, while the silicon nitride films 19 and 21 are used as a mask, the silicon layer 15 and the impurity layer 17 are etched so as to form a recessed portion 23. It is desirable that the length of a horizontal line connecting between a lower end of the sidewall 7 and the recessed portion 22 is equal to or longer than the thickness of the silicon layer 14. Similarly, it is desirable that the length of a horizontal line connecting between a lower end of the sidewall 8 and the recessed portion 23 is equal to or longer than the thickness of the silicon layer 15.

Subsequently, as shown in FIG. 8, an impurity having a high concentration is introduced into the recessed portions 22 and 23 by an ion implantation method so as to form impurity layers 24 and 25. This process may be omitted when the silicon layers 14 and 15 have a sufficiently low resistance. Furthermore, after contact holes, which will be described later, are formed, an impurity may be introduced into only bottoms of the contact holes by an ion implantation method so as to form an impurity layer on a portion of the recessed portion 22 and form an impurity layer on a portion of the recessed portion 23. Then a heat treatment is performed to activate the impurity in the impurity layers 24 and 25 as needed.

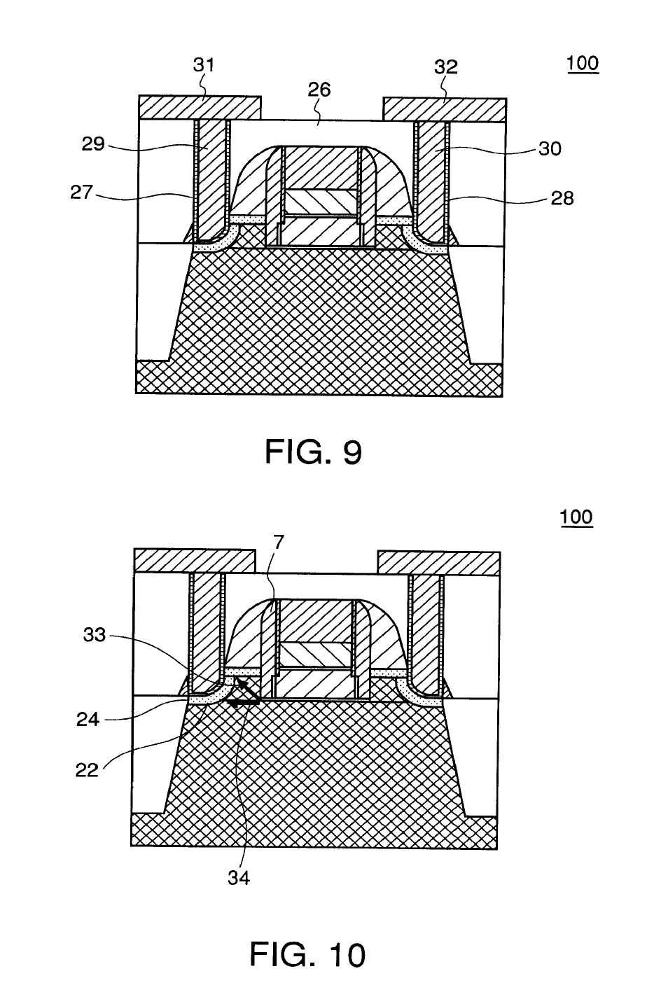

Then, as shown in FIG. 9, an interlayer dielectric 26 is formed by a general process.

Next, as shown in FIG. 10, contact holes 27 and 28 are formed in the interlayer dielectric 26 by a general process. Contacts 29 and 30 are formed within the contact holes 27 and 28, respectively. Metal interconnection layers 31 and 32 are formed on the interlayer dielectric 26. Specifically, an impurity is introduced into the contact holes 27 and 28 by an ion implantation method. A silicide layer is formed within the contact holes 27 and 28 by a general semiconductor fabrication process. Polysilicon including a doped impurity may be used as a material to be filled in the contact holes. Furthermore, the same effects can be attained even if no silicide is formed on interfaces between the polysilicon and the silicon layers 14 and 15 formed by selective epitaxial growth.

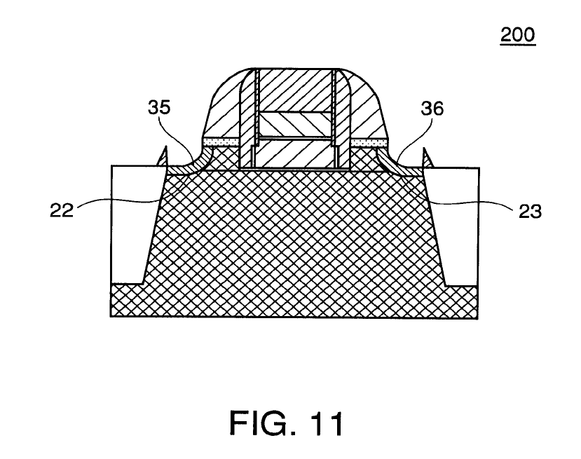

The present embodiment provides a MOS transistor having the following structure. A portion of the silicon layers 14 and 15 formed by selective epitaxial growth is removed so as to form inclination portions inclined downward in directions away from the sidewalls 7 and 8. The impurity layers 24 and 25 are formed on the inclination portions. Since the portion of the silicon layers 14 and 15, which have a high resistance, is removed, the parasitic resistance of the source and the drain is reduced in the MOS transistor. As a result, an on-state current Iₒₙ of the MOS transistor can be increased. Referring to FIG. 11, two arrows, i.e., current paths 33 and 34 extend from a lower end portion of the sidewall 7 toward the impurity layer 24 on the recessed portion 22. It can be seen that those current paths 33 and 34 have substantially the same length. In a group of lines extending radially from the lower end portion of the sidewall 7 toward the impurity layer 24, all of lines located between the current paths 33 and 34 are shorter than the current paths 33 and 34.

Next, a manufacturing method of a MOS transistor 200 according to a second exemplary embodiment of the present invention will be described.

The explanation of the first embodiment with reference to FIGS. 2 to 7 can also be applied to the second embodiment and is omitted herein.

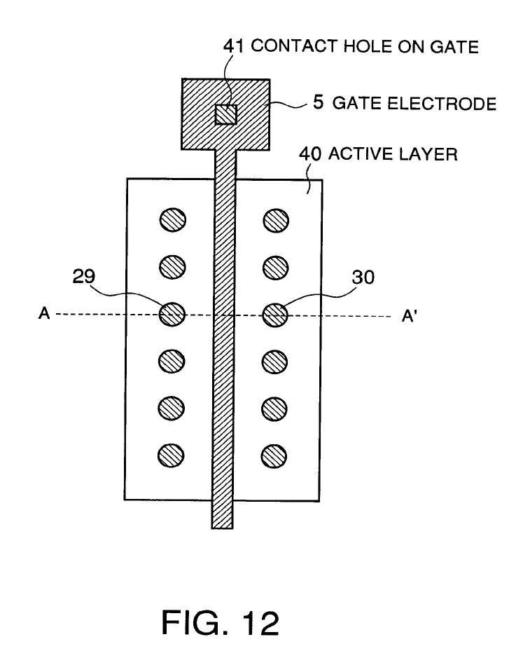

In the first embodiment, after the recessed portions 22 and 23 are formed as shown in FIG. 8, the impurity layers 24 and 25 are formed on the recessed portions 22 and 23. In the second embodiment, as shown in FIG. 12, metal or semiconductor is introduced onto the recessed portions 22 and 23 so as to form low-resistance layers 35 and 36 in a self-aligned manner. For example, cobalt and nickel are used as the metal to be introduced. However, any metals capable of forming a silicide layer can be used as the metal to be introduced. Furthermore, germanium may be introduced so as to form a silicon germanide layer.

Although the present invention has been described based on the preferred exemplary embodiments, it is not limited to the illustrated embodiments. It would be apparent to those skilled in the art that many modifications and variations may be made without departing from the spirit and scope of the present invention.

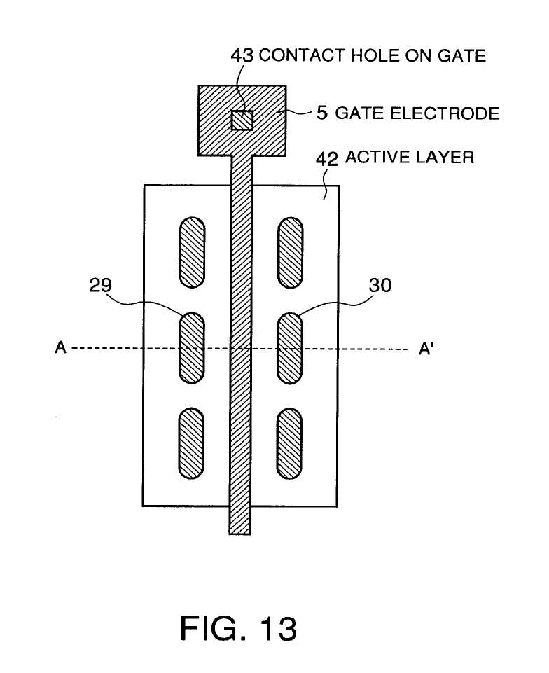

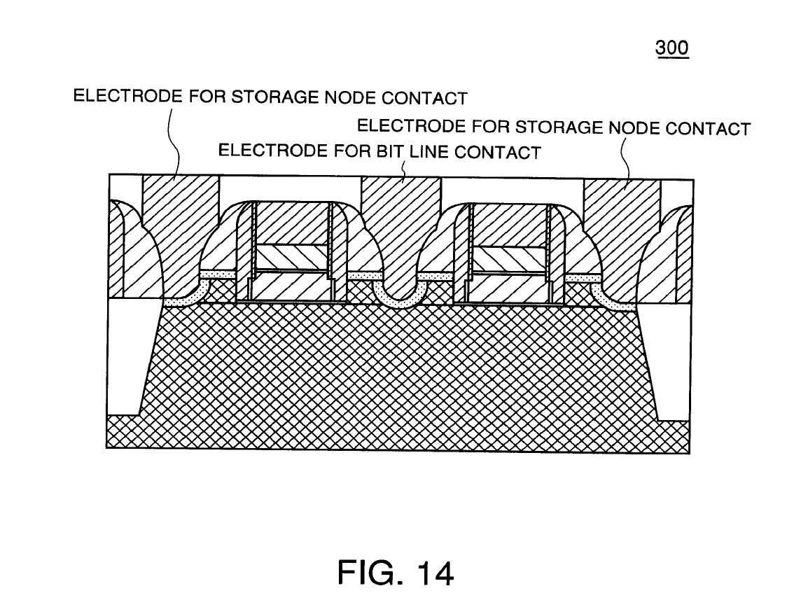

For example, the MOS transistors 100 and 200 described in the first and second embodiments are used in a portion of a semiconductor device shown in FIG. 13 or 14. FIGS. 2 to 12 correspond to a cross-sectional view taken along line A-A′ of FIG. 13 or 14. More specifically, for example, the MOS transistors 100 and 200 can be applied to a contact portion of a storage node in a DRAM. Furthermore, the MOS transistors 100 and 200 can be applied to a peripheral circuit of a DRAM.

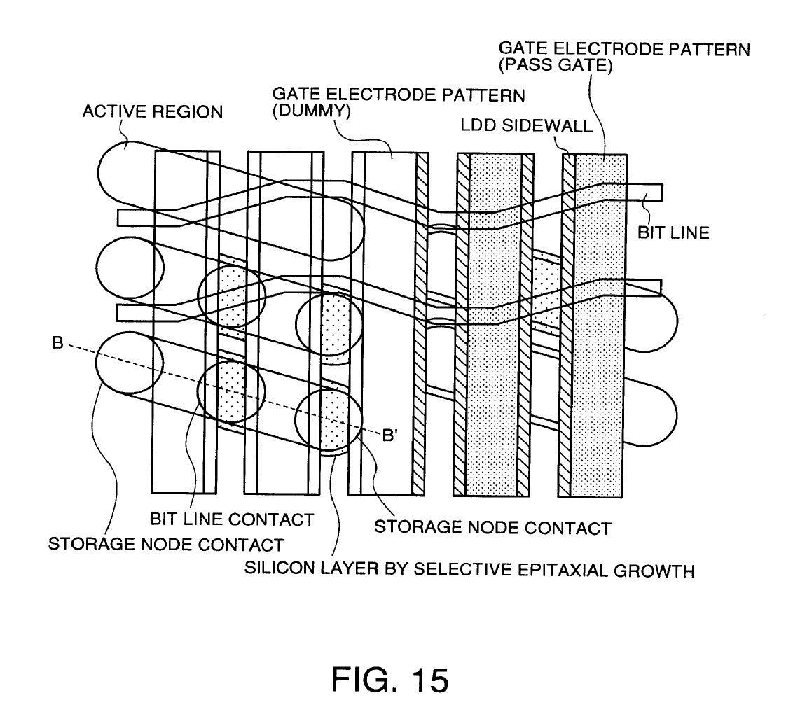

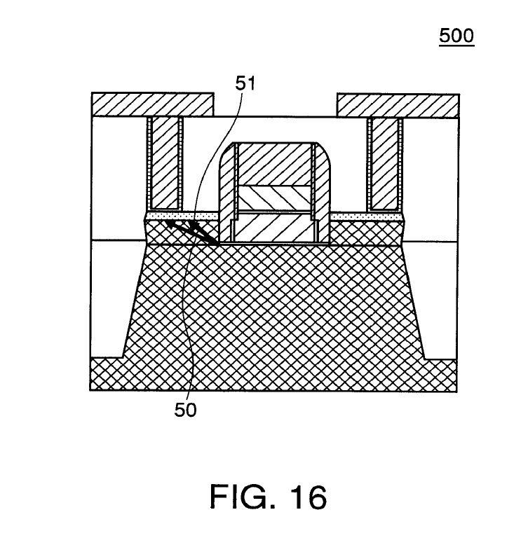

FIGS. 2 to 12 illustrate a MOS transistor having one gate located between two recessed portions. However, the present invention is not limited to the illustrated examples. For example, it would be apparent to those skilled in the art that the present invention can be applied to a MOS transistor having two gates located between two recessed portions as shown in FIGS. 15 and 16. FIG. 15 is a cross-sectional view taken along line B-B′ of a MOS transistor produced by a lithography mask pattern as shown in FIG. 16. Such a MOS transistor can be used in a pass gate portion of a DRAM having 6F2 layout.

Furthermore, it would be apparent to those skilled in the art that the present invention can be applied to a PMOS transistor and an NMOS transistor in a CMOS device.

In a case where the silicon layer has a high resistance to some extent, it is desirable that a conductive layer be provided along the inclination portion. Conversely, in a case where the silicon layer has a low resistance, such a conductive layer may not necessarily be provided.

For example, the inclination portion may be formed as a portion of a recessed portion.

It is desirable that the MOS transistor include a contact hole having a bottom formed by at least a portion of the inclination portion on the silicon layer. At that time, in a case where the silicon layer has a high resistance to some extent, it is desirable that a conductive layer be provided on the bottom of the contact hole.

Examples of the conductive layer include an impurity layer introduced by an ion implantation method and a conductive layer formed in a self-aligned manner by metal or semiconductor and the silicon layer. For example, cobalt and nickel are used as the metal. However, any metals capable of forming a silicide layer can be used as the metal. Furthermore, germanium may be used as the semiconductor. In this case, the conductive layer is a silicon germanide layer.

Examples of the contact in the contact hole include a silicide layer formed by introducing an impurity into the contact hole by an ion implantation method and polysilicon including a doped impurity.

Furthermore, an exemplary aspect of the present invention provides a semiconductor device in which the aforementioned MOS transistors are connected to each other. The semiconductor device includes a recessed portion located between two of the gates of the MOS transistors. The recessed portion is formed by connecting the inclination portions of the MOS transistors to each other. The semiconductor device also includes a contact hole having a bottom formed by the recessed portion.

Moreover, another exemplary aspect of the present invention provides a semiconductor device including the aforementioned MOS transistor.

Furthermore, another exemplary aspect of the present invention provides a method of manufacturing the aforementioned MOS transistor.

According to another exemplary aspect of the present invention, a parasitic resistance of a source and a drain is reduced in a MOS transistor. As a result, an on-state current Iₒₙ of the MOS transistor can be improved.

The above and other objects, features, and advantages of the present invention will be apparent from the following description when taken in conjunction with the accompanying drawings which illustrate preferred exemplary embodiments of the present invention by way of example.

What is claimed is:

1. A semiconductor device comprising:
a semiconductor substrate having an upper surface and a plurality of active regions;
at least one of the active regions having an active upper surface which is a part of the upper surface of the semiconductor substrate;
a plurality of gates formed on the upper surface of the semiconductor substrate, a first gate being formed on a first portion of the active upper surface;
an epitaxial semiconducting layer formed on a second portion of the active upper surface, the second portion of the active upper surface not being covered by the first gate;
a plurality of dielectric spacers, each of the dielectric spacer covering a sidewall of one of the plurality of gates;
a first dielectric spacer covering a first portion of the epitaxial semiconducting layer;
a second portion of the epitaxial semiconducting layer not being covered by any one of the plurality of dielectric spacers;
the second portion of the epitaxial semiconducting layer bordering the first portion of the epitaxial semiconducting layer and an isolation region;
the isolation region surrounding the at least one of the active regions;
an upper surface of the second portion of the epitaxial semiconducting layer being etched to have a lower height than the upper surface of the first portion of the epitaxial semiconducting layer.

2. The semiconductor device according to claim 1, wherein the second portion of the epitaxial semiconductor layer is implanted with an impurity to form an impurity layer.

3. The semiconductor device according to claim 2, further comprising a sidewall interposed between one of the plurality of gates and the first dielectric spacer.

4. The semiconductor device according to claim 3, further comprising a first current path extending from a lower end of the sidewall toward an uppermost portion of the impurity layer, and a second current path extending from the lower end of the sidewall toward a point where the impurity layer meets the active upper surface, the first and second current paths having a same length.

5. The semiconductor device according to claim 4, wherein in a group of lines extending radially from the lower end of the sidewall toward the impurity layer, each line between the first and second current paths has a length that is smaller than the length of the first and second current paths.

6. The semiconductor device according to claim 1, wherein the second portion of the epitaxial semiconductor layer slopes downward toward the second portion of the active upper surface.

7. The semiconductor device according to claim 1, further comprising a sidewall interposed between one of the plurality of gates and the first dielectric spacer.

8. The semiconductor device according to claim 7, wherein a length of a horizontal line connecting between a lower end of the sidewall and the second portion of the epitaxial semiconductor layer is greater than or equal to a thickness of the first portion of the epitaxial semiconductor layer.

9. The semiconductor device according to claim 7, wherein the second portion of the epitaxial layer is inclined downward and away from the sidewall.
